(19) United States
(12) Patent Application Publication
(10) Pub. No.: US 2019/0019893 A1
(43) Pub. Date: Jan. 17, 2019

(54) ARRAY SUBSTRATE, MANUFACTURING METHOD, AND LCD PANEL

(71) Applicant: Shenzhen China Star Optoelectronic Semiconductor Display Technology Co., Ltd., Shenzhen, Guangdong (CN)

(72) Inventor: Longqiang SHI, Shenzhen, Guangdong (CN)

(73) Assignee: Shenzhen China Star Optoelectronics Semiconductor Display Technology Co., Ltd., Shenzhen, Guangdong (CN)

(21) Appl. No.: 15/557,096

(22) PCT Filed: Aug. 22, 2017
(86) PCT No.: PCT/CN2017/098439

§ 371 Date: Sep. 9, 2017

(30) Foreign Application Priority Data
Jul. 12, 2017 (CN) 201710565730.X

(51) Int. Cl. H01L 29/786; H01L 29/26; H01L 21/28; H01L 21/3213; H01L 21/3065; H01L 21/385; H01L 29/66

(52) U.S. Cl. CPC H01L 29/7869; H01L 29/78618; H01L 29/263; H01L 21/28; H01L 27/1225; H01L 21/32139; H01L 21/3065; H01L 21/385; H01L 29/66969; H01L 21/32134

(57) ABSTRACT

An array substrate, its manufacturing method, and a liquid crystal display panel employing the array substrate are disclosed. The present disclosure forms an amorphous silicon layer, as a layer of protection, on the Thin Film Transistor (TFT) active layer so that, during the formation of the source and drain patterns by etching, the amorphous silicon layer ensures the electrical properties of the TFT channels by preventing the etching solution from contacting the active layer and thereby damaging the TFT channels.

### BACKGROUND OF THE INVENTION

### 1. Field of the Invention

The present disclosure generally relates to display techniques, and particularly relates to an array substrate, its manufacturing method, and a liquid crystal display (LCD) panel using the array substrate.

### 2. The Related Arts

Following the advancement in the dimension and resolution of liquid crystal displays (LCDs), Thin Film Transistor (TFT) becomes the mainstream technique for LCD devices. Currently, TFT active layer is mainly formed using Indium Gallium Zinc Oxide (IGZO) and, within the active layer, TFT channels are formed on the source and drain patterns. Due to that IGZO is highly sensitive in terms of its electrical properties, the channels are easily damaged during the LCD manufacturing process for example by the etching solution when forming the source and drain patterns, thereby affecting the channels' electrical properties.

### SUMMARY OF THE INVENTION

Therefor the present disclosure teaches an array substrate, its manufacturing method, and a liquid crystal display (LCD) panel using the array substrate that prevent damages to and ensure electrical properties of Thin Film Transistor (TFT) channels.

An embodiment of the array substrate manufacturing method includes the following steps.

sequentially forming a gate pattern and a gate insulation layer are a substrate;

sequentially forming an active layer, an amorphous silicon layer, a metallic layer, and a photoresist layer on the gate insulation layer;

conducting exposure and development on the photoresist layer using a half-tone mask and forming a first photoresist area and second photoresist areas to the lateral sides of the first photoresist area, where the first photoresist area has a smaller thickness than that of the second photoresist areas;

removing the active layer, the amorphous silicon layer, and the metallic layer not covered by the first and second photoresist areas by etching;

conducting an ashing process on the first and second photoresist areas so as to remove the first photoresist area but keep a portion of the second photoresist area;

removing the metallic layer not covered by the portion of the second photoresist area by etching, and forming the source and drain patterns;

removing the portion of the second photoresist area;

forming a flat layer on the gate insulation layer and covers the source and drain patterns, where the flat layer has a via exposing the drain pattern; and

forming an electrode pattern on the flat layer, where the electrode pattern contacts the drain pattern through the via.

An embodiment of the array substrate includes the following components.

a substrate;

a gate pattern and a gate insulation layer sequentially formed on the substrate;

an active layer, an amorphous silicon layer, a source pattern, and a drain pattern sequentially formed on the gate insulation layer;

a flat layer on the gate insulation layer covering the source and drain patterns, where the flat layer has a via exposing the drain pattern; and

an electrode pattern on the flat layer, where the electrode pattern contacts the drain pattern through the via.

An embodiment of the LCD panel includes an array substrate and the array substrate includes the following components.

a substrate;

a gate pattern and a gate insulation layer sequentially formed on the substrate;

an active layer, an amorphous silicon layer, a source pattern, and a drain pattern sequentially formed on the gate insulation layer;

a flat layer on the gate insulation layer covering the source and drain patterns, where the flat layer has a via exposing the drain pattern; and

an electrode pattern on the flat layer, where the electrode pattern contacts the drain pattern through the via.

The advantages of the present disclosure is that an amorphous silicon layer, as a layer of protection, on the TFT active layer so that, during the formation of the source and drain patterns by etching, the amorphous silicon layer ensures the electrical properties of the TFT channels by preventing the etching solution from contacting the active layer and thereby damaging the TFT channels.

### BRIEF DESCRIPTION OF THE DRAWINGS

To make the technical solution of the embodiments according to the present disclosure, a brief description of the drawings that are necessary for the illustration of the embodiments will be given as follows. Apparently, the drawings described below show only example embodiments of the present disclosure and for those having ordinary skills in the art, other drawings may be easily obtained from these drawings without paying any creative effort. In the drawings:

FIG. 1 is a flow diagram showing a manufacturing method of an array substrate according to a first embodiment of the present disclosure;

FIG. 2 is a schematic diagram showing the outcomes of major steps of the manufacturing method of FIG. 1;

FIG. 3 is a flow diagram showing a manufacturing method of an array substrate according to a second embodiment of the present disclosure;

FIG. 4 is a schematic diagram showing the outcomes of major steps of the manufacturing method of FIG. 3;

FIG. 5 is a flow diagram showing a method for removing light alignment impurities according to a third embodiment of the present disclosure; and

FIG. 6 is a schematic diagram showing a liquid crystal display (LCD) panel according to an embodiment of the present disclosure.

### DETAILED DESCRIPTION OF THE PREFERRED EMBODIMENTS

In the following, the present disclosure is explained in details through embodiments and accompanying drawings. It should be understood that not all possible embodiments are disclosed. Other embodiments derived from the following embodiments by a reasonably skilled person in the art without significant inventive effort should be considered to be within the scope of the present disclosure.

The major objective of the present disclosure is to form an amorphous silicon layer on the Thin Film Transistor (TFT) active layer so that, during the formation of the source and drain patterns by etching, the amorphous silicon layer ensures the electrical properties of the TFT channels by preventing the etching solution from contacting the active layer and thereby damaging the TFT channels.

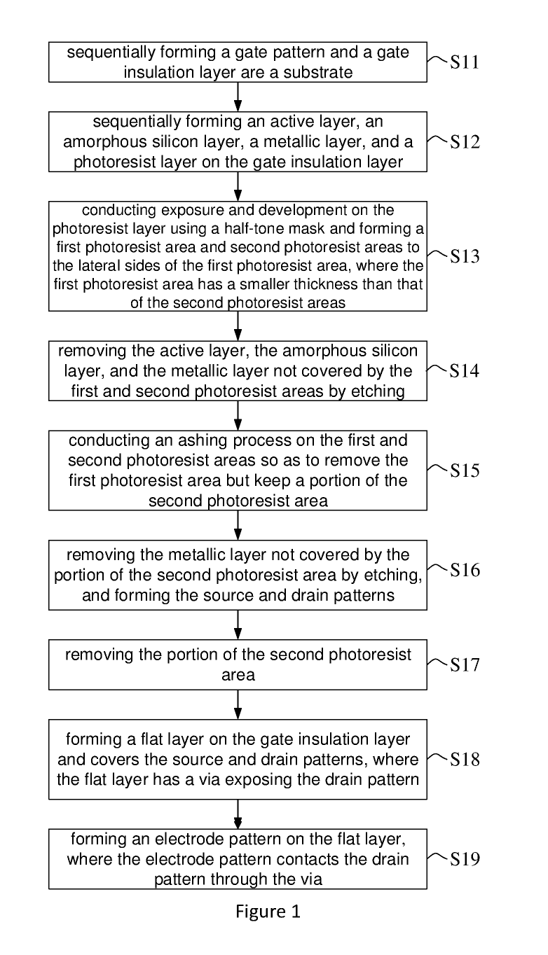

As illustrated in FIG. 1, a manufacturing method of an array substrate according to a first embodiment of the present disclosure includes the following steps S11˜S19.

In step S11, a gate pattern and a gate insulation layer are sequentially formed on a substrate.

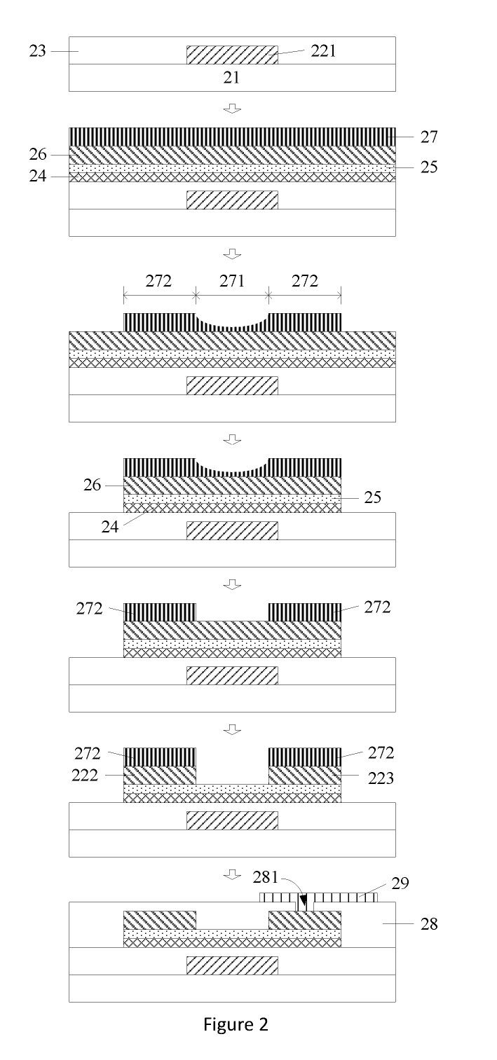

As shown in FIG. 2, the substrate 21 may be made of a translucent material such as glass, transparent plastics, or other flexible material. The substrate 21 may also include a base substrate and a passivation layer on the base substrate. The base substrate may be made of a translucent material such as glass, transparent plastics, or other flexible material. The passivation layer may be made of silicon nitride such as Si₃N₄ but is not limited as such.

In the present embodiment, the gate pattern 221 may be formed on the substrate 21 through a masking process. Specifically, a metallic layer is first formed on the substrate 21 through Physical Vapor Deposition (PVD), and a photoresist layer is coated on the metallic layer. Then, the exposure and development process is conducted on the photoresist layer through a mask. The fully exposed portion of the photoresist is removed by developer solution, and the un-exposed portion of the photoresist remains. The part of the metallic layer not covered by the photoresist is etched and then the photoresist is removed. The remaining part of the metallic layer becomes the TFT gate pattern 221.

In the present embodiment, the gate insulation layer 23 may be formed on and cover the entire the gate pattern 221 through Chemical Vapor Deposition (CVD). The gate insulation layer 23 may be made of silicon oxide (SiOₓ). To enhance its abrasion resistance and insulation performance, the gate insulation layer 23 may also include silicon oxide and silicon nitride, such as SiO₂ and Si₃N₄, sequentially formed on the gate pattern 221.

In step S12, an active layer, an amorphous silicon layer, a metallic layer, and a photoresist layer are sequentially formed on the gate insulation layer.

As shown in FIG. 2, the active layer 24 may be made of Indium Gallium Zinc Oxide (IGZO). The active layer 24, the amorphous silicon (a-Si) layer 25, the metallic layer 26, and the photoresist layer 27 are complete layers formed by various methods which the present disclosure imposes no constraint.

In step S13, exposure and development are conducted on the photoresist layer using a half-tone mask and thereby forming a first photoresist area and second photoresist areas to the lateral sides of the first photoresist area. The first photoresist area has a smaller thickness than that of the second photoresist areas.

As shown in FIG. 2, after the exposure and development process using the half-tone mask, unexposed portion of the photoresist remains, the fully exposed portion is removed, and the partially exposed portion is not wholly removed by developer solution. Therefore, the remaining photoresist layer 27 includes the first photoresist area 271, and the second photoresist areas 272 to the lateral sides of the first photoresist area 271. The first photoresist area 271 has the smallest thickness, and the second photoresist areas 272 may have an identical thickness.

In step S14, the active layer, the amorphous silicon layer, and the metallic layer not covered by the first and second photoresist areas are etched.

In the present embodiment, a wet etching process may be applied to the metallic layer 26. That is, by submerging the first and second photoresist areas 271 and 272 in the etching solution, the portion of the metallic layer 26 not covered by the first and second photoresist areas 271 and 272 reacts with and dissolves in the etching solution. The other portion of the metallic layer 26 covered by the first and second photoresist areas 271 and 272 then remains. Furthermore, a dry etching process may be applied to the amorphous silicon layer 25, and a wet etching process may be applied to the active layer 24.

In step S15, an ashing process is conducted on the first and second photoresist areas so as to remove the first photoresist area but keep a portion of the second photoresist area.

After the ashing process, the first photoresist area 271 is removed, and the second photoresist area remains but has a smaller thickness.

In step S16, the metallic layer not covered by the portion of the second photoresist area is etched and the source and drain patterns are formed.

In the present embodiment, the wet etching process may be again applied to the metallic layer 26. The portion of the metallic layer 26 not covered by the portion of the second photoresist area 272 does not react with the etching solution and remains and therefore forms the source pattern 222 and the drain pattern 223. The space between the source pattern 222, the drain pattern 223, and the active layer 24 may be deemed as the TFT channel, and the channel layer is above the active layer and between the second photoresist areas 272.

In step S17, the portion of the second photoresist area is removed.

In step S18, a flat layer is formed on the gate insulation layer and covers the source and drain patterns. The flat layer includes a via exposing the drain pattern.

In the present embodiment, the flat layer 28 is formed to cover the source and drain patterns 222 and 223 through a masking process. Specifically, an entire silicon oxide layer is formed through CVD, an entire photoresist layer is then coated on the silicon oxide layer, and then exposure and development is conducted through a mask. The fully exposed portion of the photoresist is removed by developer solution, and the un-exposed portion of the photoresist remains. The part of the silicon oxide layer not covered by the photoresist is etched to form the via 281 exposing the drain pattern 223. Finally, the photoresist is removed and the remaining silicon oxide layer becomes the flat layer 28.

In step S19, an electrode pattern is formed on the flat layer and contacts the drain pattern through the via.

In the present embodiment, the electrode pattern 29 is formed through a masking process according to existing arts. The electrode pattern 29 is the pixel electrodes of the array substrate, and its material may be Indium Tin Oxide (ITO).

As described above, the present embodiment forms an amorphous silicon layer 25 as a protection layer on TFT channels so that, during the formation of the source and drain patterns 222 and 223 by etching, the amorphous silicon layer 25 ensures the electrical properties of the TFT channels by preventing the etching solution from contacting the active layer 24 and thereby damaging the TFT channels.

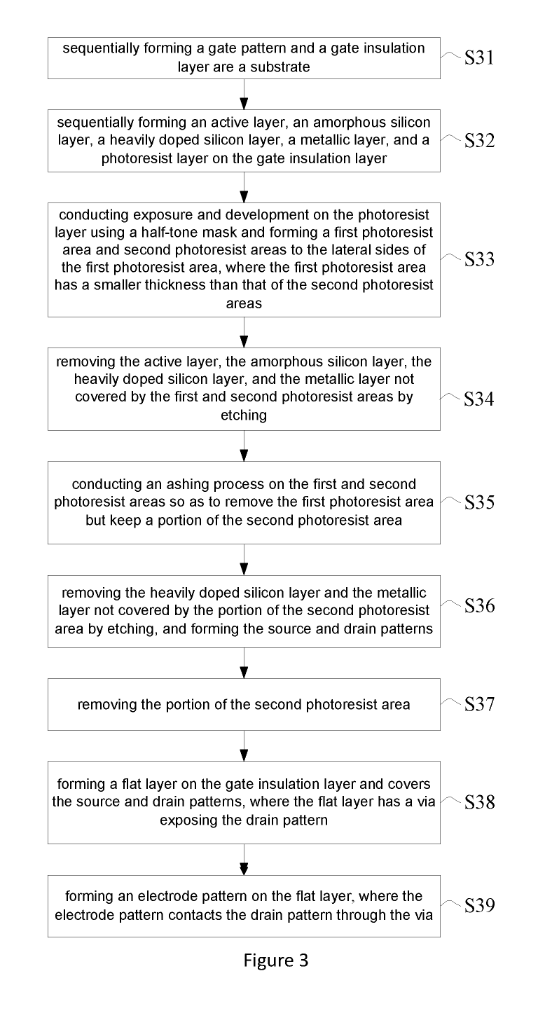

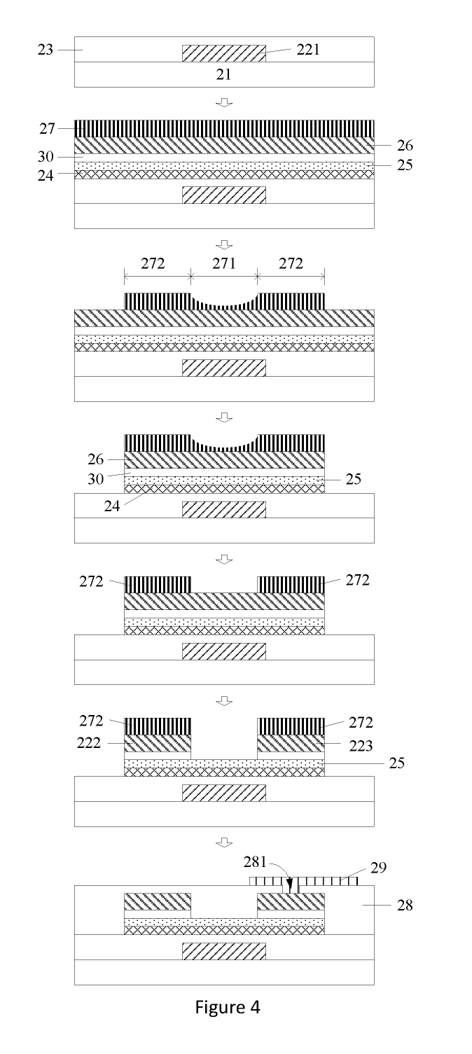

As illustrated in FIG. 3, a manufacturing method of an array substrate according to a second embodiment of the present disclosure includes the following steps S31˜S39. FIG. 4 is a schematic diagram showing the outcomes of major steps of the manufacturing method, and elements in FIG. 4 are numbered identically to those same elements in FIG. 2.

In step S31, a gate pattern and a gate insulation layer are sequentially formed on a substrate.

In step S32, an active layer, an amorphous silicon layer, a heavily doped silicon layer, a metallic layer, and a photoresist layer are sequentially formed on the gate insulation layer.

In step S33, exposure and development are conducted on the photoresist layer using a half-tone mask and thereby forming a first photoresist area and second photoresist areas to the lateral sides the first photoresist area. The first photoresist area has a smaller thickness than that of the second photoresist areas.

In step S34, the active layer, the amorphous layer, the heavily doped silicon layer, and the metallic layer not covered by the first and second photoresist areas are etched.

In step S35, an ashing process is conducted on the first and second photoresist areas so as to remove the first photoresist area but keep a portion of the second photoresist area.

In step S36, the heavily doped silicon layer and the metallic layer both not covered by the portion of the second photoresist area are etched and the source and drain patterns are formed.

In step S37, the portion of the second photoresist area is removed.

In step S38, a flat layer is formed on the gate insulation layer and covers the source and drain patterns. The flat layer includes a via exposing the drain pattern.

In step S39, an electrode pattern is formed on the flat layer and contacts the drain pattern through the via.

What is different from the previous embodiment lies in the inclusion of a heavily doped silicon layer 30 between the amorphous silicon layer 25 and the metallic layer 26 in step S32. The heavily doped silicon layer 30 may be doped with n+ ion impurities. For example, the heavily doped silicon layer 30 includes n+Si. In addition, in the etching process of step S34, a portion of the heavily doped silicon layer 30 not covered by the first and second photoresist areas 271 and 272 is removed by etching. Furthermore, in the etching process of step S36, a portion of the heavily doped silicon layer 30 not covered by the second photoresist areas 272 is removed by etching. In the array substrate produced by the present embodiment, heavily doped silicon layers 30 are formed between the amorphous silicon layer 25 and the drain pattern 223, and between the amorphous silicon layer 25 and the source pattern 222. The heavily doped silicon layers 30 improves the amorphous silicon layer 25's electrical contacts with the source and drain patterns 222 and 223, so as to ensure the electrical properties of the TFT channels.

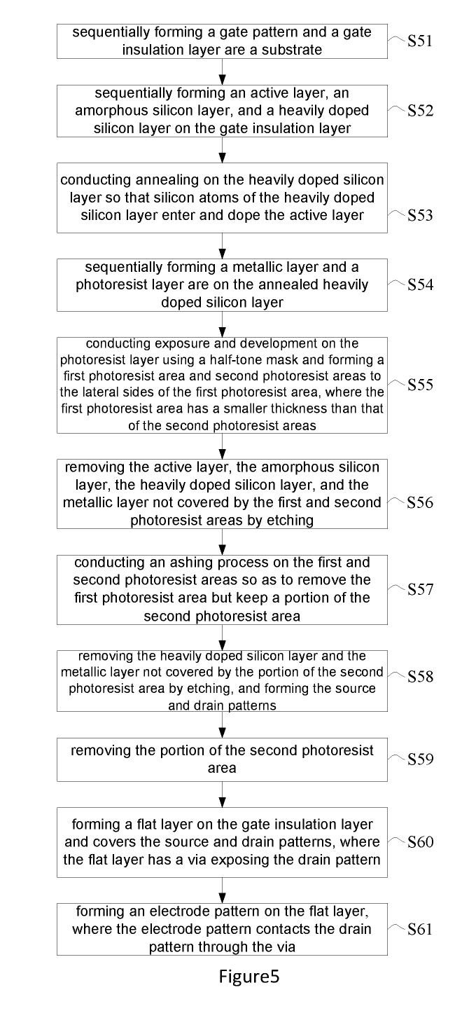

As illustrated in FIG. 5, a manufacturing method of an array substrate according to a third embodiment of the present disclosure includes the following steps S51˜S61, and elements are numbered identically to those same elements in FIG. 4.

In step S51, a gate pattern and a gate insulation layer are sequentially formed on a substrate.

In step S52, an active layer, an amorphous silicon layer, and a heavily doped silicon layer are sequentially formed on the gate insulation layer.

In step S53, annealing is conducted on the heavily doped silicon layer so that silicon atoms of the heavily doped silicon layer enter and dope the active layer.

In step S54, a metallic layer and a photoresist layer are sequentially formed on the annealed heavily doped silicon layer.

In step S55, exposure and development are conducted on the photoresist layer using a half-tone mask and thereby forming a first photoresist area and second photoresist areas to the lateral sides the first photoresist area. The first photoresist area has a smaller thickness than that of the second photoresist areas.

In step S56, the active layer, the amorphous layer, the heavily doped silicon layer, and the metallic layer not covered by the first and second photoresist areas are etched.

In step S57, an ashing process is conducted on the first and second photoresist areas so as to remove the first photoresist area but keep a portion of the second photoresist area.

In step S58, the heavily doped silicon layer and the metallic layer both not covered by the portion of the second photoresist area are etched and the source and drain patterns are formed.

In step S59, the portion of the second photoresist area is removed.

In step S60, a flat layer is formed on the gate insulation layer and covers the source and drain patterns. The flat layer includes a via exposing the drain pattern.

In step S61, an electrode pattern is formed on the flat layer and contacts the drain pattern through the via.

During the annealing process, Si atoms in the heavily doped silicon layer 30 diffuse into the active layer 24 which becomes doped active layer 24 such as an N+IGZO layer. Si-doped IGZO better withstands reversed bias and light irradiation than un-doped IOGZO does. The present embodiment therefore may further enhance the electrical stability of TFT.

Through the above methods, a desired array substrate is produced.

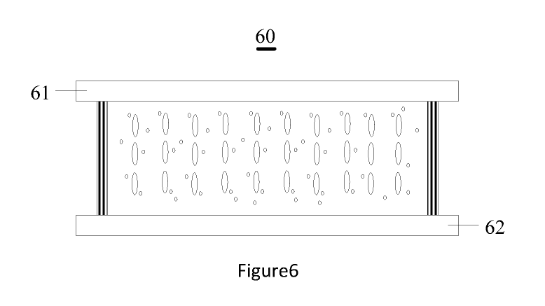

The present disclosure also teaches a liquid crystal display (LCD) panel. As shown in FIG. 6, the LCD panel 60 includes an array substrate 61 and a color film substrate 62. The array substrate 61 may be one produced by one of the above methods, and LCD panel 60 therefore enjoys the same advantages.

Embodiments of the present disclosure have been described, but not intending to impose any unduly constraint to the appended claims. Any modification of equivalent structure or equivalent process made according to the disclosure and drawings of the present disclosure, or any application thereof, directly or indirectly, to other related fields of technique, is considered encompassed in the scope of protection defined by the claims of the present disclosure.

What is claimed is:

1. A manufacturing method for an array substrate, comprising the steps of
sequentially forming a gate pattern and a gate insulation layer are a substrate;
sequentially forming an active layer, an amorphous silicon layer, a metallic layer, and a photoresist layer on the gate insulation layer;
conducting exposure and development on the photoresist layer using a half-tone mask and forming a first photoresist area and second photoresist areas to the lateral sides of the first photoresist area, where the first photoresist area has a smaller thickness than that of the second photoresist areas;
removing the active layer, the amorphous silicon layer, and the metallic layer not covered by the first and second photoresist areas by etching;
conducting an ashing process on the first and second photoresist areas so as to remove the first photoresist area but keep a portion of the second photoresist area;
removing the metallic layer not covered by the portion of the second photoresist area by etching, and forming the source and drain patterns;
removing the portion of the second photoresist area;
forming a flat layer on the gate insulation layer and covers the source and drain patterns, where the flat layer has a via exposing the drain pattern; and
forming an electrode pattern on the flat layer, where the electrode pattern contacts the drain pattern through the via.

2. The manufacturing method as claimed in claim 1, further comprising the steps of:
forming a heavily doped silicon layer between the amorphous silicon layer and the metallic layer;
wherein the step of removing the active layer, the amorphous silicon layer, and the metallic layer not covered by the first and second photoresist areas by etching comprises the step of removing the active layer, the amorphous silicon layer, the heavily doped silicon layer, and the metallic layer not covered by the first and second photoresist areas by etching; and the step of removing the metallic layer not covered by the portion of the second photoresist area by etching comprises the step of removing the heavily doped silicon layer and the metallic layer not covered by the portion of the second photoresist area by etching.

3. The manufacturing method as claimed in claim 2, wherein the step of sequentially forming an active layer, an amorphous silicon layer, a metallic layer, and a photoresist layer on the gate insulation layer comprises the steps of:
sequentially forming the active layer, the amorphous silicon layer, and the heavily doped silicon layer on the gate insulation layer;
conducting annealing on the heavily doped silicon layer so that Si atoms in the heavily doped silicon layer enter and dope the active layer; and
sequentially forming the metallic layer and the photoresist layer on the annealed heavily doped silicon layer.

4. The manufacturing method as claimed in claim 3, wherein the heavily doped silicon layer is doped with n+ ion impurities.

5. The manufacturing method as claimed in claim 2, wherein the step of removing the active layer, the amorphous silicon layer, and the metallic layer not covered by the first and second photoresist areas by etching comprises the steps of:
conducting wet etching to the metallic layer;
conducting dry etching to the heavily doped silicon layer and the amorphous silicon layer; and
conducting web etching to the active layer.

6. An array substrate, comprising
a substrate;
a gate pattern and a gate insulation layer sequentially formed on the substrate;
an active layer, an amorphous silicon layer, a source pattern, and a drain pattern sequentially formed on the gate insulation layer;
a flat layer on the gate insulation layer covering the source and drain patterns, where the flat layer has a via exposing the drain pattern; and
an electrode pattern on the flat layer, where the electrode pattern contacts the drain pattern through the via.

7. The array substrate as claimed in claim 6, further comprising:
heavily doped silicon layers between the amorphous silicon layer and the drain pattern, and between the amorphous silicon layer and the source pattern.

8. The array substrate as claimed in claim 7, wherein the active layer is doped with Si atoms diffused from the heavily doped silicon layer during annealing.

9. The manufacturing method as claimed in claim 7, wherein the heavily doped silicon layer is doped with n+ ion impurities.

10. A liquid crystal display (LCD) panel comprising an array substrate, wherein the array substrate comprises:
a substrate;
a gate pattern and a gate insulation layer sequentially formed on the substrate;
an active layer, an amorphous silicon layer, a source pattern, and a drain pattern sequentially formed on the gate insulation layer;
a flat layer on the gate insulation layer covering the source and drain patterns, where the flat layer has a via exposing the drain pattern; and
an electrode pattern on the flat layer, where the electrode pattern contacts the drain pattern through the via.

11. The LCD panel as claimed in claim 10, further comprising:
heavily doped silicon layers between the amorphous silicon layer and the drain pattern, and between the amorphous silicon layer and the source pattern.

12. The LCD panel as claimed in claim 11, wherein the active layer is doped with Si atoms diffused from the heavily doped silicon layer during annealing.

13. The LCD panel as claimed in claim 11, wherein the heavily doped silicon layer is doped with n+ ion impurities.
